(19) United States
(12) Patent Application Publication
(10) Pub. No.: US 2024/0274591 A1
(43) Pub. Date: Aug. 15, 2024

(54) SEMICONDUCTOR DEVICE WITH COMMUNICATION RING

(71) Applicant: Silicon Storage Technology, Inc., San Jose, CA (US)

(72) Inventors: Jinho KIM, San Jose, CA (US); CYNTHIA FUNG, San Jose, CA (US); PARVIZ GHAZAVI, San Jose, CA (US); JEAN FRANCOIS THIERY, Vaucluse (FR); CATHERINE DECOBERT, Pourrieres (FR); GILLES FESTES, Fuveau (FR); BRUNO VILLARD, Aix en Provence (FR); YURI TKACHEV, Sunnyvale, CA (US); XIAN LIU, Sunnyvale, CA (US); NHAN DO, Saratoga, CA (US)

(21) Appl. No.: 18/110,318

(22) Filed: Feb. 15, 2023

(51) Int. Cl. H01L 27/02; H01L 21/38; H01L 23/58

(52) U.S. Cl. CPC H01L 27/0207; H01L 21/38; H01L 23/585

(57) ABSTRACT

A semiconductor device includes a semiconductor substrate, a first module of circuitry formed on the semiconductor substrate, a second module of circuitry formed on the semiconductor substrate, and a communication ring that encircles the first module of circuitry. The communication ring includes an insulation material disposed over the semiconductor substrate, a plurality of electrical connectors disposed over the semiconductor substrate and extending across a width of the communication ring, and a conductive diffusion in the semiconductor substrate that encircles the first module of circuitry.

### FIELD OF THE INVENTION

The present disclosure relates to semiconductor devices.

### BACKGROUND OF THE INVENTION

A semiconductor device includes electrical circuits formed on a semiconductor substrate. The electrical circuits can be arranged in different areas of the semiconductor substrate according to function or design source, without limitation. For example, as shown in FIG. 1, semiconductor device 1 includes a semiconductor substrate 10 that can include different modules of circuitry (also known as functional blocks) 12, containing different circuits. Each module of circuitry 12 can be designed separately, and connected to the other modules of circuitry 12, other circuits or pins, without limitation, on the semiconductor substrate 10 with lines or busses, without limitation. By arranging the electrical circuits in a plurality of discrete modules of circuitry 12, this allows the circuits in each module of circuitry 12 to be designed separately, for eventual inclusion with and connection to other circuits on the semiconductor substrate 10. The completed semiconductor substrate 10, with all the modules of circuitry 12 formed thereon, is commonly referred to as a semiconductor device 1 (also can be referred to as a semiconductor chip).

One advantage of segregating circuits in a semiconductor device into discrete modules of circuitry is that it allows semiconductor device manufactures to acquire the design of one or modules of circuitry from separate sources (e.g., different parties or suppliers) specializing in certain types of circuitry. For example, the manufacturer of the semiconductor device 1 of FIG. 1 could acquire the design of module of circuitry 12A from a separate source that specializes in that circuitry. As a non-limiting example, module of circuitry 12A could be embedded non-volatile memory circuitry that is designed to support other circuitry on semiconductor substrate 10. The semiconductor device manufacture can save costs by acquiring the design of module of circuitry 12A from the separate source.

There is a need to integrate the various modules of circuitry on semiconductor substrate 10.

### BRIEF SUMMARY OF THE INVENTION

The aforementioned problems and needs are addressed by a semiconductor device that includes a semiconductor substrate, a first module of circuitry formed on the semiconductor substrate, a second module of circuitry formed on the semiconductor substrate, and a communication ring that encircles the first module of circuitry. The communication ring includes an insulation material disposed over the semiconductor substrate, a plurality of electrical connectors disposed over the semiconductor substrate and extending across a width of the communication ring, and a conductive diffusion in the semiconductor substrate that encircles the first module of circuitry.

A semiconductor device includes a semiconductor substrate, a module of circuitry formed on the semiconductor substrate, and a communication ring that encircles the module of circuitry. The communication ring includes an insulation material disposed over the semiconductor substrate, a plurality of electrical connectors disposed over the semiconductor substrate and extending across a width of the communication ring, and a conductive diffusion in the semiconductor substrate that encircles the module of circuitry.

A method of forming a semiconductor device includes forming a first module of circuitry on the semiconductor substrate, and forming a communication ring that encircles the first module of circuitry. The communication ring includes an insulation material disposed over the semiconductor substrate, a plurality of electrical connectors disposed over the semiconductor substrate and extending across a width of the communication ring, and a conductive diffusion in the semiconductor substrate that encircles the first module of circuitry.

Other objects and features of the present disclosure will become apparent by a review of the specification, claims and appended figures.

### BRIEF DESCRIPTION OF THE DRAWINGS

FIG. 1 is a plan view of a semiconductor device of the prior art.

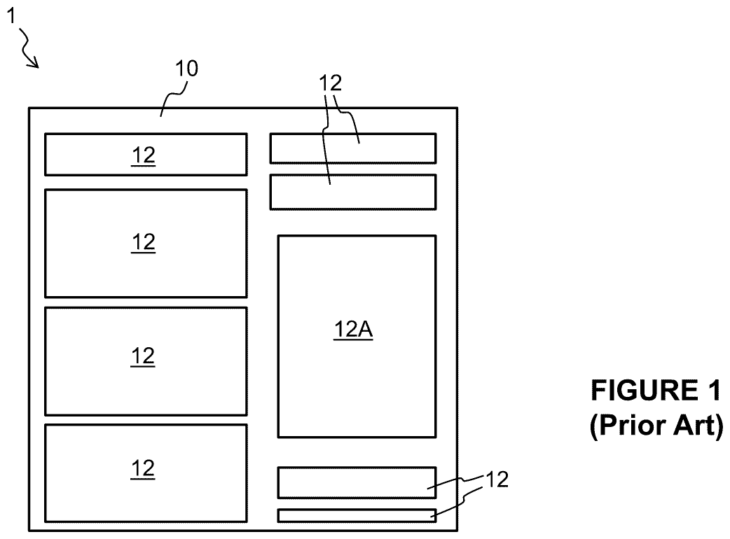

FIG. 2 is a plan view of a semiconductor device with a communication ring.

FIG. 3 is a plan view of a semiconductor device with a communication ring.

FIG. 4 is a plan view of a semiconductor device with a communication ring.

FIG. 5 is a partial plan view of a semiconductor device with a communication ring.

### DETAILED DESCRIPTION OF THE INVENTION

The present disclosure is directed to techniques for integrating modules of circuitry in semiconductor devices.

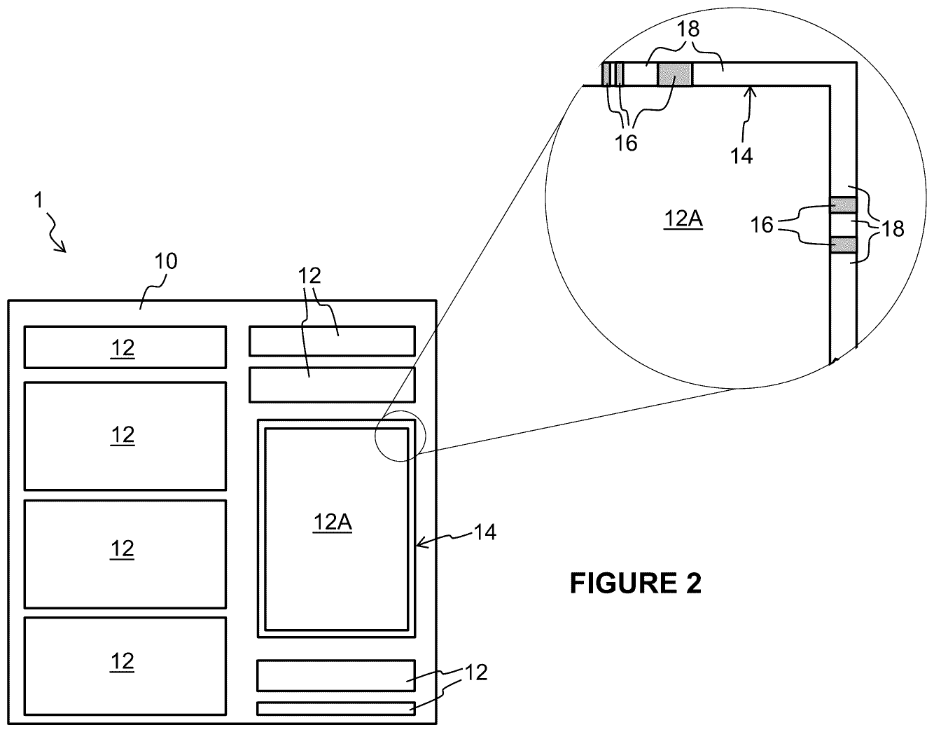

The circuits in a module of circuitry can be proprietary to the separate source providing it, while the circuits in the rest of the semiconductor device can be proprietary to the semiconductor device manufacturer (i.e., the party responsible for the design and manufacture of the semiconductor device as a whole). One way to protect both parties is for the separate source and the semiconductor device manufacturer to separately share their respective modules of circuitry only with the semiconductor fab (also referred to as a foundry) that actually manufactures the semiconductor device, so that neither the semiconductor manufacturer nor the separate source need direct access to the design of the circuits of the other. For example, as shown in FIG. 2, the designs for all the modules of circuitry 12 in the semiconductor device 1 can be provided by the semiconductor device manufacturer to the foundry, while the separate source provides the design for module of circuitry 12A to the foundry. With such an arrangement, the semiconductor device manufacturer and the separate source only need to agree on how the circuits of the module of circuitry 12A are to be connected to the circuits and lines in the remainder of the semiconductor device 1.

One way for the semiconductor device manufacturer and the separate source to agree on such connections is shown in FIG. 2, where a communication ring 14 is provided around (e.g., encircles) the module of circuitry 12A. Communication ring 14 includes electrical connectors 16 at known locations and insulation material 18 (e.g., silicon dioxide), between and under respective electrical connectors 16, which electrical connectors 16 and insulation material 18 are disposed over the semiconductor substrate. Respective ones of the electrical connectors 16 are comprised of conductive material (e.g., metal) extending across the width of the communication ring 14 (for providing signals across the width of that portion of the communication ring 14). The insulation material 18 of the communication ring 14 is disposed between and under the electrical connectors 16 (i.e., the electrical connectors 16 are disposed over and insulated from the surface of semiconductor substrate 10 by respective portions of insulation material 18). While FIG. 2 shows only a single layer of electrical connectors 16 and insulation material 18, one skilled in the art would appreciate that semiconductor devices can have multiple layers of metal and related interconnections. Therefore, communication ring 14 can have multiple layers of electrical connectors 16 and insulation material 18, where the positioning and sizes of the electrical connectors 16 can vary layer to layer.

For any given module of circuitry 12A, the semiconductor device manufacturer and separate party can determine the appropriate configuration of the communication ring 14 (i.e., known locations of electrical connections 16), without sharing the specific circuit designs to which the communication ring 14 is connected. Specifically, knowing the configuration of the communication ring 14, the semiconductor device manufacturer can design its portion of the semiconductor device 1 to electrically connect to the communication ring 14 and therefore to the circuitry inside the communication ring 14 (i.e., module of circuitry 12A), without having any specific knowledge of the circuit design of module of circuitry 12A. Similarly, the separate source can design module of circuitry 12A to electrically connect to the communication ring 14 and therefore to the circuitry of the semiconductor device 1 outside of the communication ring 14 without having any specific knowledge of the design of that circuitry.

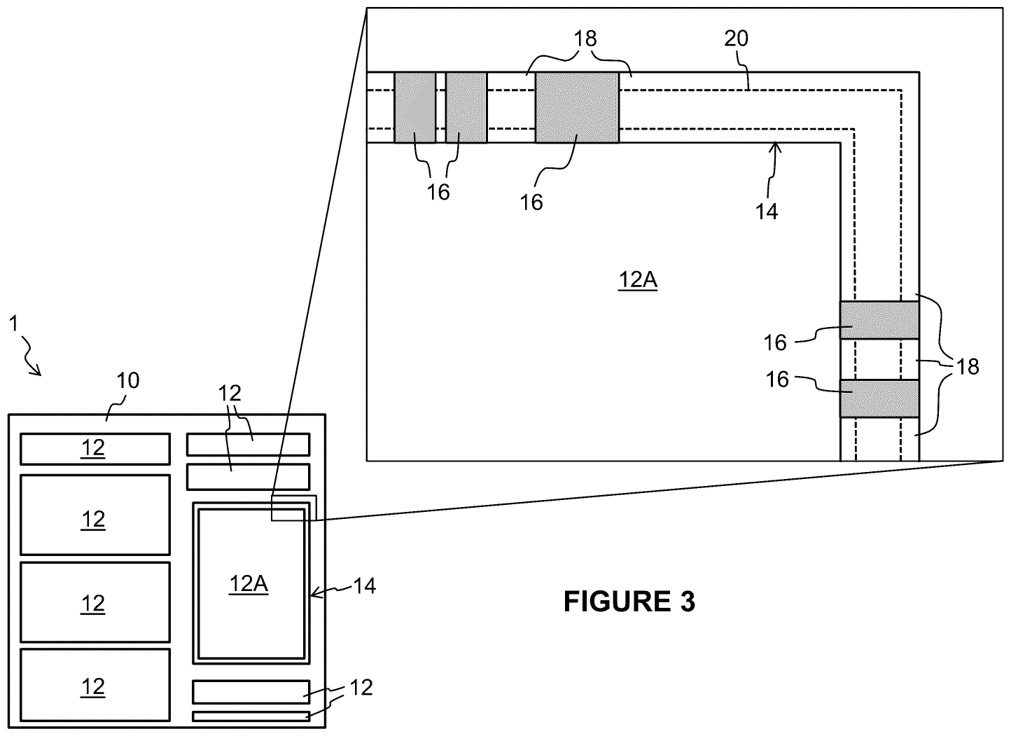

It has been discovered by the present inventors that a number of advantages are attained by the communication ring 14 including conductive diffusion 20 in the semiconductor substrate 10 that extends along the length of the communication ring 14 (i.e., conductive diffusion 20 encircles module of circuitry 12A, and can be disposed under or offset from one or both of the insulation material 18 and electrical connectors 16), as shown in FIG. 3. Conductive diffusion 20 can be the same diffusion used to form the source and drain regions for transistors formed on the semiconductor substrate 10. For example, for p− type semiconductor substrates 10, the conductive diffusion 20 can be n+ type, such as phosphorous or arsenic. For n− type semiconductor substrates 10, the conductive diffusion 20 can be p+ type, such as boron or BF₂. The conductive diffusion 20, being electrically conductive, can be connected to ground or a voltage source such as Vdd. For example, p+ type conductive diffusion 20 can be connected to ground, and n+ type conductive diffusion 20 can be connected to Vdd.

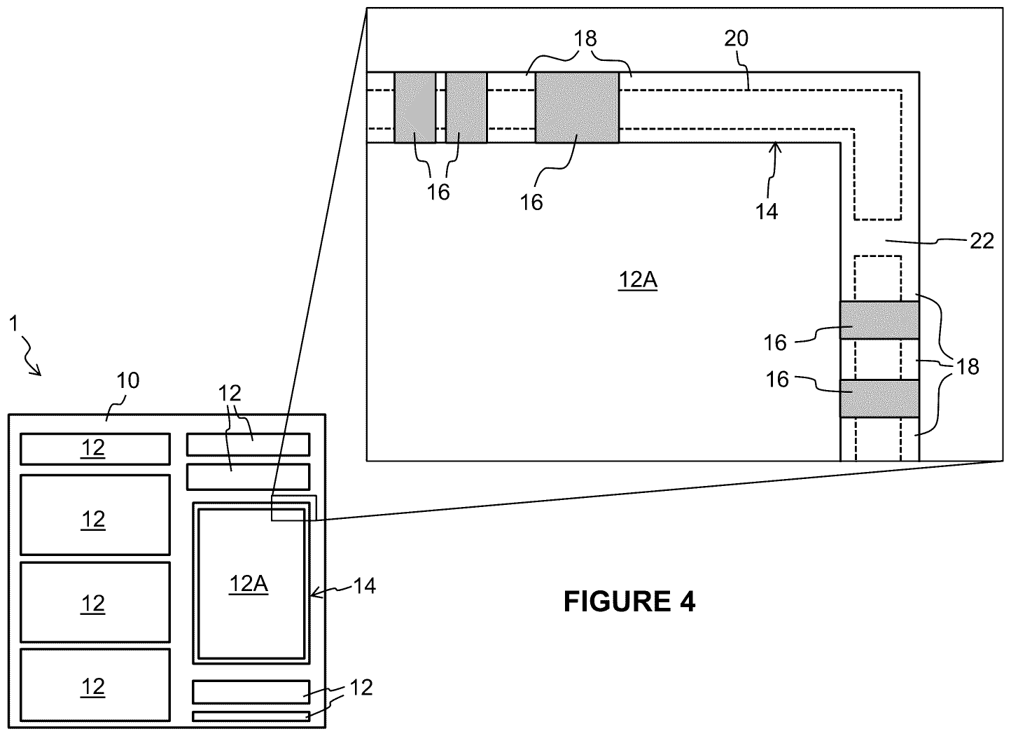

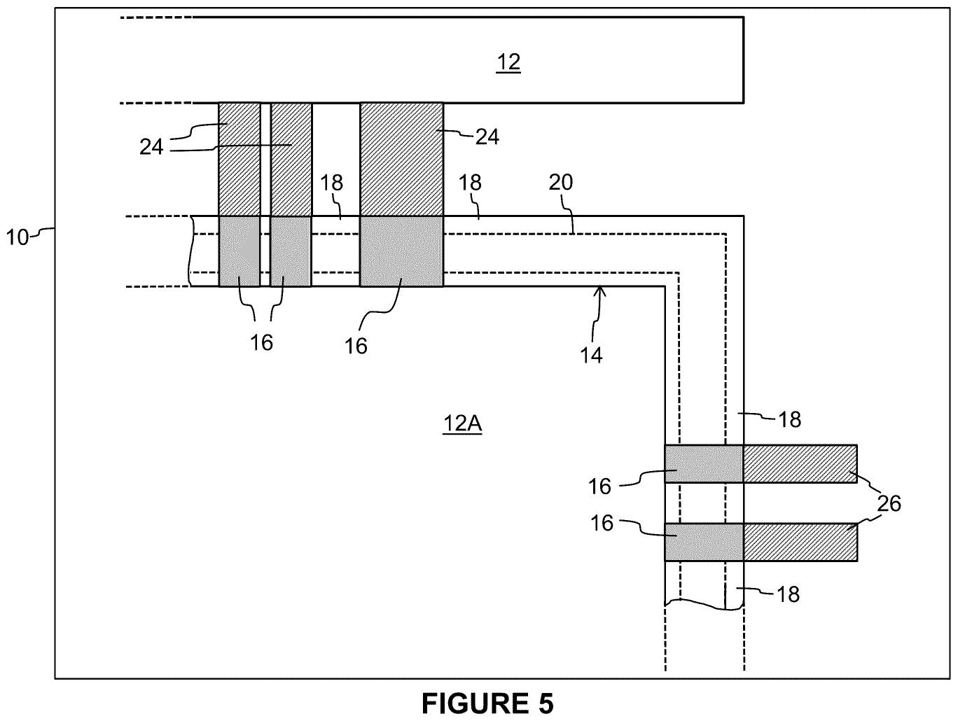

Conductive diffusion 20 can be a continuous line with no gaps, so that conductive diffusion 20 completely encircles the module of circuitry 12A. Alternately, conductive diffusion 20 can be a discontinuous line that includes one or more gaps 22 in the conductive diffusion 20, so that the conductive diffusion 20 encircles, with one more gaps, the module of circuitry 12A, as shown in FIG. 4 (which allows for different portions of the conductive diffusion 20 to be respectively connected to different voltage or ground sources). FIG. 5 illustrates conductive lines 24 that electrically connect electrical connectors 16 (of communication ring 14 for module of circuitry 12A—e.g., a first module of circuitry) to a module of circuitry 12 (e.g., a second module of circuitry) elsewhere on semiconductor substrate 10. Also shown are conductive lines 26 electrically connecting electrical connectors 16 (of communication ring 14 for module of circuitry 12A) to other portions, components or pins of semiconductor substrate 10 (e.g., power and ground).

The inclusion of conductive diffusion 20 in the portion of the semiconductor substrate 10 that is part of the communication ring 14 provides increased stability. Specifically, conductive diffusion 20 can collect electrons or holes generated by circuitry outside the communication ring 14 thereby preventing the collected electrons or holes from crossing the communication ring 14 and interfering with circuitry of module of circuitry 12A, thereby reducing or eliminating circuit interference. Reduction or elimination of interference can be enhanced by connecting the conductive diffusion 20 to ground (e.g., for p− type conductive diffusion 20) or a voltage source such as Vdd (e.g., for n− type conductive diffusion 20). Further, the inclusion of conductive diffusion 20 in communication ring 14 can allow diffusion-based design rules to be skipped when finalizing the design of the communication ring 14 portion of the semiconductor device. Finally, the conductive diffusion 20 can also assist in meeting minimum diffusion design rules for the areas of the semiconductor device 1 adjacent the communication ring 14. Specifically, a dummy diffusion may be formed in semiconductor substrate 10 in order to meet minimum diffusion design rules. Conductive diffusion 20 can assist meeting diffusion design rules for the area of semiconductor device in and around communication ring 14.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are examples only, and should not be deemed to limit the claims. Single layers of material could be formed as multiple layers of such or similar materials, and vice versa. Lastly, the terms “forming” and “formed” as used herein shall include material deposition, material growth, or any other technique in providing the material as disclosed or claimed.

What is claimed is:

1. A semiconductor device, comprising:
a semiconductor substrate;
a first module of circuitry formed on the semiconductor substrate;
a second module of circuitry formed on the semiconductor substrate; and
a communication ring that encircles the first module of circuitry, wherein the communication ring includes:
an insulation material disposed over the semiconductor substrate,
a plurality of electrical connectors disposed over the semiconductor substrate and extending across a width of the communication ring, and
a conductive diffusion in the semiconductor substrate that encircles the first module of circuitry.

2. The semiconductor device of claim 1, wherein the conductive diffusion is formed as a continuous line that completely encircles the first module of circuitry.

3. The semiconductor device of claim 1, wherein the conductive diffusion is formed as a discontinuous line that encircles, with one or more gaps, the first module of circuitry.

4. The semiconductor device of claim 1, wherein the semiconductor substrate is p− type, and the conductive diffusion is n+ type.

5. The semiconductor device of claim 1, wherein the semiconductor substrate is n− type, and the conductive diffusion is p+ type.

6. The semiconductor device of claim 4, wherein the conductive diffusion is electrically connected to a voltage source.

7. The semiconductor device of claim 5, wherein the conductive diffusion is electrically connected to a ground source.

8. The semiconductor device of claim 1, further comprising:
a conductive line electrically connecting one of the plurality of electrical connectors to the second module of circuitry.

9. The semiconductor device of claim 1, further comprising:
a plurality of conductive lines respectively electrically connected to the plurality of electrical connectors.

10. A semiconductor device, comprising:
a semiconductor substrate;
a module of circuitry formed on the semiconductor substrate; and
a communication ring that encircles the module of circuitry, wherein the communication ring includes:
an insulation material disposed over the semiconductor substrate,
a plurality of electrical connectors disposed over the semiconductor substrate and extending across a width of the communication ring, and
a conductive diffusion in the semiconductor substrate that encircles the module of circuitry.

11. The semiconductor device of claim 10, wherein the conductive diffusion is formed as a continuous line that completely encircles the module of circuitry.

12. The semiconductor device of claim 10, wherein the conductive diffusion is formed as a discontinuous line that encircles, with one or more gaps, the module of circuitry.

13. The semiconductor device of claim 10, wherein the semiconductor substrate is p− type, and the conductive diffusion is n+ type.

14. The semiconductor device of claim 10, wherein the semiconductor substrate is n− type, and the conductive diffusion is p+ type.

15. The semiconductor device of claim 13, wherein the conductive diffusion is electrically connected to a voltage source.

16. The semiconductor device of claim 14, wherein the conductive diffusion is electrically connected to a ground source.

17. The semiconductor device of claim 10, further comprising:
a plurality of conductive lines respectively electrically connected to the plurality of electrical connectors.

18. A method of forming a semiconductor device, comprising:
forming a first module of circuitry on the semiconductor substrate; and
forming a communication ring that encircles the first module of circuitry, wherein the communication ring includes:
an insulation material disposed over the semiconductor substrate,
a plurality of electrical connectors disposed over the semiconductor substrate and extending across a width of the communication ring, and
a conductive diffusion in the semiconductor substrate that encircles the first module of circuitry.

19. The method of claim 18, wherein the conductive diffusion is formed as a continuous line that completely encircles the first module of circuitry.

20. The method of claim 18, wherein the conductive diffusion is formed as a discontinuous line that encircles, with one or more gaps, the first module of circuitry.

21. The method of claim 18, further comprising:
forming a second module of circuitry on the semiconductor substrate; and
forming a conductive line electrically connecting one of the plurality of electrical connectors to the second module of circuitry.
